(19) United States
(12) Patent Application Publication
(10) Pub. No.: US 2026/0086181 A1
(43) Pub. Date: Mar. 26, 2026

(54) Method and Localization Systems for Localizing a Portable Component of an Imaging System During an Examination Procedure, and Imaging Systems

(71) Applicant: Siemens Healthineers AG, Forchheim (DE)

(72) Inventor: Thomas Rühr, Erlangen (DE)

(73) Assignee: Siemens Healthineers AG, Forchheim (DE)

(21) Appl. No.: 19/336,698

(22) Filed: Sep. 23, 2025

(30) Foreign Application Priority Data
Sep. 23, 2024 (DE) 10 2024 209 088.3

(51) Int. Cl. G01R 33/54

(52) U.S. Cl. CPC G01R 33/543

(57) ABSTRACT

The disclosure relates to methods and localization systems for localizing a portable component of an imaging system. For an examination procedure, the portable component is arranged on the patient. A localization method may include emitting an optical localization signal in an imaging area of the imaging modality by an optical transmitter, receiving the emitted optical localization signal by an optical receiver arranged on the portable component, transmitting the received optical localization signal by an optical transmission path to an electronic evaluation unit situated outside an examination room, and localizing the portable component by the electronic evaluation unit based on the received optical localization signal.

### CROSS REFERENCE TO RELATED APPLICATIONS

This patent application claims priority to German Patent Application No. 102024209088.3, filed Sep. 23, 2024, which is incorporated herein by reference in its entirety.

### BACKGROUND

The present disclosure relates to a method for localizing a portable component of an imaging system during an examination procedure on a patient using an imaging modality of the imaging system, wherein for the examination procedure the portable component is arranged on the patient.

The disclosure further relates to an electronic localization system for localizing a portable component of an imaging system during an examination procedure using an imaging modality of the imaging system, wherein for the examination procedure the portable component can be arranged on the patient.

The disclosure further relates to an electronic imaging system having an imaging modality, with at least one portable component and one electronic localization system.

The disclosure likewise relates to a method for localizing a portable component of an imaging system during an examination procedure on a patient using an imaging modality of the imaging system, wherein for the examination procedure the portable component is arranged on the patient.

The disclosure further relates to an electronic localization system for localizing a portable component of an imaging system during an examination procedure on a patient using an imaging modality of the imaging system, wherein for the examination procedure the portable component is arranged on the patient.

The disclosure further relates to an imaging system having an imaging modality, having at least one portable component and having an electronic localization system.

With the help of imaging systems an imaging method, in particular an imaging diagnostic investigation, can be performed on the patient. In this case, instrument-based examination methods can be performed, especially with the imaging system, these for example being able to provide two-or three-dimensional image data about organs and structures of the patient. As examples of an imaging system, mention can for example be made of a magnetic resonance tomography system (MRT system) and a computed tomography system (CT system). Further different types of imaging systems are likewise known.

In magnetic resonance tomography, knowledge about the position of the coils used is important during an examination procedure, referred to for example as a scan procedure. This is especially important for the subsequent reconstruction of images, such as MRT images for example. Such coils may be local coils, for example body coils. Multiple such coils especially can be used for the examinations. These coils can be designed to be flexible, in order to be able to attach them to the corresponding areas of the patient's body. The information about the position or movement of the body parts of the patient, such as extremities or a respiratory movement by the patient, is likewise of importance in addition to the coil position, in order to be able to carry out a correspondingly good image reconstruction with a corresponding image quality. The position of the patient and/or the movement of the patient can be used as triggers for the magnetic resonance tomography sequence. If too much movement of the patient during the examination procedure is noted, the patient can thus for example be told to keep still and/or to breathe more calmly, in order not to influence the measurements too much. If this is in turn the case, the measurements, in particular the scans, would have to be repeated.

To date, patient movements can be detected by various means, for example by attached sensors or external cameras. The presence of cameras especially can be unpleasant for the patient. In particular, due to the very high levels of radiation in the area of the imaging system, the camera shots can be negatively influenced. The position of the coil is currently not explicitly considered, since as regards the imaging sequence it is assumed that the coil position remains fixed during the imaging sequence.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 shows a schematic representation of an imaging system, according to an exemplary embodiment, which makes possible a localization system for localizing a portable component and thus a patient within the imaging models.

FIG. 2 shows the localization system from FIG. 1 according to an exemplary embodiment of the present disclosure.

FIG. 3 shows an exemplary operational sequence of the localization of the portable component and thus of the patient, according to an exemplary embodiment of the present disclosure, using the localization system from FIG. 2.

FIG. 4 shows the localization system from FIG. 1 according to an exemplary embodiment of the present disclosure.

FIG. 5 shows an exemplary operational sequence of a localization, according to an exemplary embodiment of the present disclosure, using the localization system from FIG. 4.

FIG. 6 shows an arrangement of the transmission facilities of the localization system from FIG. 4 in the area of an imaging modality of the imaging system from FIG. 1, according to an exemplary embodiment of the present disclosure.

FIG. 7 shows a schematic representation of a body coil as a portable component of an imaging system from FIG. 1 and the receiving elements arranged thereon, according to an exemplary embodiment of the present disclosure.

FIG. 8 shows a configuration of optical fibers to couple with a receiving element on the body coil from FIG. 7, according to an exemplary embodiment of the present disclosure, to conduct signals outside the scope of examination of the imaging system.

The exemplary embodiments of the present disclosure will be described with reference to the accompanying drawings. Elements, features and components that are identical, functionally identical and have the same effect are - insofar as is not stated otherwise - respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the present disclosure is to be able to perform an improved, in particular more reliable, localization, in particular position determination, of a portable component of an imaging system, wherein the portable component can be a body coil or another object supported by the patient.

A first aspect of the disclosure relates to a method for localizing a portable component of an imaging system during an examination procedure on a patient using an imaging modality of the imaging system. For the examination procedure, the portable component may be arranged on the patient. The method may include:
emission of at least one optical localization signal in an imaging area of the imaging modality, within which the patient is located during the examination procedure, by at least one optical transmission element,
receipt of the at least one emitted optical localization signal by at least one optical receiving element arranged on the portable component,
transmission of the at least one received optical localization signal by means of an optical transmission path to an electronic evaluation unit, situated outside an examination room in which the imaging modality is arranged, and
localization of the portable component by the electronic evaluation unit on the basis of the at least one received optical localization signal.

Thanks to the proposed method a better localization of the component supported on the patient during the examination procedure can be performed. By performing the localization on the basis of optical signals and thus an optical signal evaluation, the localization can be performed so that as regards the imaging of the imaging system no negative influences result therefrom. Since especially in imaging systems such as an MRT system, very strong fields are present in the examination room, the at least one received optical localization signal per optical transmission path, for example an optical fiber, can be transmitted outside the examination room, so that the evaluation of the received optical localization signal can be performed outside the examination room.

Thanks to the optical localization method which can be realized with the proposed method, continuous localization and thus continuous position tracking of the portable component on the patient can especially be performed. This can help to ensure that an improved image reconstruction and thus an image with a better image quality can be generated, in particular can be provided, with the imaging system. Contrary to the methods to date, an adjustment sequence measurement can be dispensed with, so that the evaluation of the images and in particular of the scans can be accelerated.

The portable component can be an item of the imaging system that can be supported on the patient. This portable item on the patient is used to track or monitor the patient's position and/or movement during the examination procedure. Furthermore, it is conceivable for the portable component to be designed as a flexible coil or local coil of the imaging system. The imaging modality, by means of which the actual examination procedure, i.e. the scanning procedure, can be performed on the patient, can especially be situated inside the examination room. Controllers of the imaging system and an electronic evaluation unit can both be situated outside the examination room. Thus they are protected against the strong electromagnetic or magnetic fields in the examination room.

The electronic evaluation unit can be an evaluation system or a computing unit. The optical transmission element can be referred to as a transmitting unit and can be arranged in the area of the imaging modality. It is further conceivable here for multiple such optical transmission elements to be arranged inside the imaging area, so that depending on the circumstances multiple optical localization signals can be emitted. This means a better localization can be performed.

The optical localization signal can be an optical signal, in particular a light-based signal. The emitted optical localization signal can be received by the optical receiving element, which is a receiving unit. This optical receiving element or multiple such optical receiving elements can be arranged on the portable component. Thus light can here for example be emitted from the transmission elements to the portable component. In particular, the emission takes place inside the imaging area, which can for example represent the patient tunnel. Thus depending on where the portable component is situated, a receiving procedure can be carried out on the basis of the emitted optical signals. The one received optical localization signal or multiple such optical signals can in turn be transmitted to the evaluation unit for evaluation by means of the optical transmission path or by means of multiple optical transmission paths. Corresponding signal processing, in particular optical signal processing, can be performed with the electronic evaluation unit, so that information can be generated here which can be used for the localization of the portable component during the examination procedure. The proposed method can be a computer-implemented method.

In one exemplary embodiment (of the first aspect) it is provided that on the basis of the at least one received optical localization signal a signal propagation time of the emitted and received at least one optical localization signal is determined by the electronic evaluation unit, wherein transmission information about the emission of the at least one optical localization signal is provided to the electronic evaluation unit and this is considered when determining the signal propagation time. Thanks to the emitted optical signal, which can be correspondingly received and processed, information as regards the localization of the portable component can for example be determined on the basis of a propagation time procedure. On the basis of the emitted and received optical localization signal which was transmitted to the evaluation unit via the optical transmission path, the signal propagation time of the emitted and received localization signal can be determined. In particular, the optical localization signal can be a time-of-flight (ToF) signal.

In other words, the optical localization signal can for example be emitted as a light pulse or as light. Thus a time, such as the signal propagation time, from emission to receipt can be determined. For this purpose, the information regarding the emission, i.e. the emission procedure, can be provided to the evaluation unit. For this purpose, the transmitting unit can likewise be connected to the evaluation unit via an optical transmission path.

Thus a propagation time can in each case be determined for the one optical localization signal as well as for further optical localization signals.

In one exemplary embodiment (of the first aspect) it is provided that on the basis of the signal propagation time a spacing between the at least one optical transmission element and the at least one optical receiving element can be determined by the electronic evaluation unit, wherein on the basis of the determined spacing a position of the at least one optical receiving element is determined. The portable component can be localized on the basis of the position of the at least one optical receiving element. In other words, thanks to optical signal processing the position of the receiving elements, in particular of the one receiving element, is determined. For this purpose, a wide variety of signal processing methods, such as triangulation for example, can be used. Based on the position of the receiving element, the portable component can in turn be localized, since the receiving element is arranged at or on the portable component.

Based on a propagation time procedure a spacing between a transmitter and a receiver can thus be determined as a function of the respective signal propagation time of the emitted and received optical localization signal. This is because the time required is directly proportional to the distance or spacing. Thus a distance between the transmitter and the receiver can be ascertained here. On the basis of the signal propagation time, the spacing and/or further information or signals, the position of the receiving element and thus of the portable component can for example be determined by means of trilateration.

For this purpose, it is further advantageous if multiple optical localization signals are emitted by means of different transmission elements and are received by multiple receiving elements at the portable component. Thus multiple spaces can be determined from this plurality, so that they can be used in position determination and in particular in trilateration.

The optical localization signal may in particular not be a laser light, but a simple diffuse light, the amplitude of which can be modulated. This means the phase of the received signal can be compared with the transmitted signal, from which the distance can then be calculated. The signal can be modulated such that essentially no aliasing can occur, in particular in the area of the patient table.

In one exemplary embodiment of the aspect (first aspect) it is provided that, in addition to the at least one optical localization signal, which has a first wavelength, at least one further optical localization signal, which has a second wavelength different from the first wavelength, is emitted with at least one further optical transmission element. The at least one further optical localization signal is received by the at least one optical receiving element or at least one further optical receiving element, which is arranged on the portable component, wherein the at least one received further optical localization signal is considered when localizing the portable component. By emitting multiple optical signals, multiple spaces or distances between the transmitters and the receivers can be determined, so that this can advantageously be used in the position determination of the receivers and in particular in the localization or position determination of the portable component. The optical localization signals can thus each be emitted with different wavelengths. Here especially a wavelength of the electromagnetic spectrum in the range from ultraviolet to infrared can be considered.

A further aspect (second aspect) relates to an electronic localization system for localizing a portable component of an imaging system during an examination procedure on a patient using an imaging modality of the imaging system. The portable component for the examination procedure can be arranged on the patient. The system may include:
at least one optical transmission element, which can be arranged on the imaging modality, wherein the at least one optical transmission element is designed to emit at least one optical localization signal in an imaging area of the imaging modality, within which the patient is situated during the examination procedure,
at least one optical receiving element, which can be arranged on the portable component, wherein the at least one optical receiving element is designed to receive the at least one emitted optical localization signal, and
an electronic evaluation unit, which can be arranged outside an examination room in which the imaging modality can be arranged.

The electronic evaluation unit may be connected to the at least one optical receiving element by means of an optical transmission path, so that the at least one received optical localization signal can be transmitted to the electronic evaluation unit. The electronic evaluation unit may be configured to localize the portable component on the basis of the at least one received optical localization signal.

With the proposed electronic localization system an imaging procedure of an imaging system can be improved, since an improved localization of a component that can be supported by the patient can be performed. Thus firstly the position of the portable component and therefore the position and movement of the patient can be determined or monitored more reliably. This is especially advantageous for the image reconstruction of the images of the patient acquired by means of the imaging modality.

In particular, the electronic localization system can be designed to execute or perform a method in accordance with the previous aspect (first aspect) or an advantageous development thereof. Specifically, the explanations for the method in accordance with the first aspect also apply (analogously) for the localization system in accordance with the second aspect.

The electronic localization system is designed so that it can be integrated into an imaging system. For this purpose, the optical transmission element or multiple such optical transmission elements can be arranged on the imaging modality, in order especially to be able to emit optical localization signals in the imaging area of the imaging modality. The at least one receiving element or multiple such receiving elements can be arranged on the portable component of the imaging system, which can be an item that can be supported by the patient, or a local coil. The electronic evaluation unit is in particular placed outside the examination room in which the imaging modality, and thus the area with an increased electromagnetic field, is situated.

The transmission element and/or the receiving element can each be connected to the evaluation unit via optical transmission paths, so that an optical signal transmission can be performed in the area outside the examination room, in order to be able in turn to carry out the signal processing and in particular the localization of the portable component.

In one form of embodiment of the further aspect (second aspect) it is provided that the at least one optical transmission element is connected to the electronic evaluation unit by means of a further optical transmission path. Thus the evaluation unit can be provided with information about the emission procedure and the receiving procedure as regards the optical localization signal, in order on the basis thereof to be able for example to determine a signal propagation time and a distance between the emitted and received optical signal. This information can especially be used firstly in order to be able to carry out the position of the at least one receiving element and thus the localization of the portable component in the imaging area.

In particular, the at least one optical transmission path and the further optical transmission path can be designed as optical waveguides. Specifically, these can be optical fiber lines or optical fiber connections. Thus here the corresponding optical signals can be transmitted from the transmitting and receiving unit to the evaluation unit via optical fibers for example. Thanks to this optical signal transmission no essentially negative interference can be made or can occur to the imaging process within the examination room. Furthermore, the influence of the strong magnetic fields or electromagnetic fields in the examination room on the signal processing can be minimized, since the for example optical fibers are influenced here less by the imaging system, and the corresponding evaluation is performed outside the examination room and outside the interfering fields.

A further aspect (third aspect) of the disclosure relates to an imaging system having an imaging modality, at least one portable component and an electronic localization system in accordance with the previous aspect (second aspect) or an advantageous development thereof. The imaging system can for example be designed as an MRT system or CT system. With the help of the imaging modality, examinations can correspondingly be carried out on a patient on the basis of magnetic fields.

The at least one optical transmission element of the electronic localization system is arranged on the imaging modality. It is here arranged such that with the help of the transmission element optical signals can be emitted in the imaging area in which the patient is situated during an examination procedure. The at least one receiving element can be arranged on the portable component, such as a local coil, of the imaging system. The electronic evaluation unit is, as already mentioned a number of times, arranged outside the examination room of the imaging system, so that the magnetic and/or electromagnetic fields do not interfere with the signal evaluation and the subsequent further processing.

A further aspect (fourth aspect) of the disclosure relates to a method for localizing a portable component of an imaging system during an examination procedure on a patient using an imaging modality of the imaging system. For the examination procedure, the portable component may be arranged on the patient. The method may include:
emission of at least one first optical localization signal in a surrounding area of the imaging modality by a first optical transmission facility, which is arranged spaced apart from the imaging modality in the surrounding area,
emission of at least one second optical localization signal in the surrounding area of the imaging modality by a second optical transmission facility which is arranged spaced apart from the first optical transmission facility and which is arranged spaced apart from the imaging modality in the surrounding area,
receipt of the emitted first and second optical localization signal by at least one optical receiving element which is arranged on the portable component,
transmission of the received first and second optical localization signal by means of an optical transmission path to an electronic evaluation unit which is situated outside an examination room in which the imaging modality is arranged, and
localization by the electronic evaluation unit of the portable component on the basis of the first and second optical localization signal.

Thanks to the proposed method an improved localization of the portable component, which can be a portable item or a local coil, can be performed. An optical localization method can especially be applied here. In particular, the localization can here be performed on the basis of light.

On the basis of the emitted optical localization signals in the examination room a reliable localization of the portable component and thus of the patient supporting the portable component can be performed. This means patient tracking can be performed during the examination procedure, without in particular cameras or other sensors being required. By emitting optical signals and the corresponding evaluation of these optical signals an efficient localization of the portable component and thus a localization of the patient during the examination procedure can be performed. By evaluating the optical signals outside the examination room the influence of a corresponding piece of evaluation equipment on the imaging system and vice versa can here be prevented or minimized.

The two transmission facilities or multiple such transmission facilities can each be spaced apart from one another and in particular can be arranged spaced apart from the imaging modality in the area surrounding the imaging modality. In other words, the two transmission facilities are situated inside the examination room in addition to the imaging modality. The two transmission facilities can especially be arranged in the surrounding area and therefore in the examination area so that the surrounding area can be captured at least in part, in particular in full, with the emitted optical localization signals. The at least one optical receiving element or multiple receiving elements can be arranged on, in particular can be fastened to, the portable component. Thus the emitted optical localization signals are received where the portable component and thus the patient are situated. The received optical localization signals can in turn be transmitted to the electronic evaluation unit via the optical transmission path.

Specifically, the explanations for the method in accordance with the first aspect likewise apply (analogously) for methods in accordance with the fourth aspect. For example, the optical signal can be a laser signal, in particular a laser light. Here the optical signals are emitted in a range such that these optical signals are not hazardous for the patient.

In one form of embodiment of the further aspect (fourth aspect) it is provided that on the basis of the received first optical localization signal an angle determination between the first optical transmission facility and the at least one optical receiving element is performed and on the basis of the received second optical localization signal an angle determination between the second optical transmission facility and the at least one optical receiving element is performed, and transmission information about the emission of the first and second optical localization signal is provided to the electronic evaluation unit and this is considered in the angle determinations. This means it is possible to determine the angle at which the receiving element in each case received or captured the optical signals.

In one form of embodiment of the further aspect (fourth aspect) it is provided that on the basis of the angle determinations a position of the at least one optical receiving element is determined, and on the basis of the position of the at least one optical receiving element the portable component is localized.

In other words, the position of the receiving elements, in particular of the one receiving element, is determined by optical signal processing. For this purpose, it is possible to use a wide variety of signal processing methods, such as triangulation for example. On the basis of the position of the receiving element the portable component can in turn be localized, since the receiving element is arranged at or on the portable component.

For this purpose, it is furthermore advantageous if multiple optical localization signals are emitted by means of different transmission elements and these are received by multiple receiving elements on the portable component. Thus multiple spacings can be determined from this plurality, so that these can be used in position determination and in particular in triangulation.

In particular, on the basis of the ascertained or determined information about the first emitted and received optical localization signal, a first angle determination can be performed and analogously a second angle determination as regards the second optical localization signal can be performed. Thus an angle can be determined here at which a respective transmission element stands to the respective transmission facility. For this purpose, a triangulation or other mathematical methods can be used. Thanks to the multiple angle determinations or angle measurements an improved position determination of the receiving element and thus a better localization of the portable component can be performed. In other words, on the basis of the emitted signal and of the respective spacing between the transmission facility and the receiving element a position and in particular an orientation of the receiving element or of the multiple receiving elements in respect of the transmission facilities can be ascertained. From this a localization, in particular a position determination, of the portable component and thus of the patient can be performed.

In one form of embodiment of the further aspect (fourth aspect) it is provided that at least one synchronization signal is sent to the at least one receiving element with the first and/or second optical transmission facility, wherein the receipt of the first and second optical localization signal is performed on the basis of the synchronization signal received by the at least one receiving element. Since especially a continuous transmission of the laser beam or laser signal or laser light as an optical signal can be performed with the transmission facilities, the transmission element must be triggered or notified accordingly when a corresponding receipt has to be performed. For example, from the time of the receipt of the synchronization signal, a time measurement can be performed until an optical localization signal is received. This in turn can be used to determine the spacing between the signal facilities and the receiving facility.

In other words, there is a synchronization here between the transmission facility and the receiving element, in order to be able to determine the propagation time as precisely or accurately as possible.

Alternatively it is provided that a synchronization signal is emitted into the surrounding area with a transmitting unit of the imaging modality, so that the synchronization signal can be received by the first and second optical transmission facility, and if the synchronization signal was received by the first and second optical transmission facility, a synchronization procedure is performed prior to the emission of the first and second optical localization signal in each case. In this case, the imaging modality itself can be used to specify when a localization of the portable component and thus of the patient is to be performed. This can take place by way of an operator of the imaging system or by a corresponding controller. Because the synchronization signal is emitted by the imaging modality, additional transmission elements can be dispensed with in this regard. In other words, a synchronization of the two transmission facilities and of the respective transmission of the transmission facilities can be performed here by emitting the synchronization signal. This is especially advantageous for a subsequent triangulation as regards the emitted and received optical signals, in order therefrom to be able to perform the position of the receiving element and thus of the portable component as efficiently as possible.

In one form of embodiment of the further aspect (fourth aspect) it is provided that the first and second optical localization signals each sweep the surrounding area in a defined rhythm as a laser line in an alternately different orientation, wherein from a point in time of the receipt of the at least one synchronization signal a period of time is determined by when at least one of the emitted laser lines is received by the receiving element, wherein this determined period of time is considered in the angle determinations.

In other words, the first and second optical localization signals are each emitted as a laser line in an alternately different orientation in the surrounding area, wherein from a point in time of the receipt of the at least one synchronization signal a period of time is determined by when at least one of the emitted laser lines is received by the receiving element, wherein this determined period of time is considered in the angle determinations. In other words, laser lines are continuously emitted (for example alternately horizontally and vertically). As soon as the receiving element has detected the synchronization signal, a reset or restart can be performed, so that as from this reset the period of time can be determined by when one of the laser lines can be detected. This period of time can then be used for angle determination. Triangulation can be used for this purpose.

The localization signals, which are configured as laser lines or laser signals, can roam or sweep the surrounding area in a cyclically recurring or cyclically repeating manner. With regard to the laser lines, at least the respective angular velocity (as regards the emission) can be specified, i.e. known. On the basis of the period of time and the information specified about the laser lines, an angle can be determined from the point of view of the transmission facilities. Triangulation can then in turn be used to determine the position of the receiver.

For example, the procedure just explained can also be considered for multiple receiving elements. Here these receiving elements could be connected to one another, so that the position and/or orientation of the portable component can be determined on the basis of the individual angle determinations.

A further aspect of the disclosure (fifth aspect) relates to an electronic localization system for localizing a portable component of an imaging system during an examination procedure on a patient using an imaging modality of the imaging system. The portable component may be arranged on the patient for the examination procedure. The system may include:
a first optical transmission facility, which can be arranged spaced apart from the imaging modality, wherein the first optical transmission facility is designed to emit at least one first optical localization signal in a surrounding area of the imaging modality,
a second optical transmission facility which is arranged spaced apart from the first optical transmission facility, and which can be arranged spaced apart from the imaging modality, wherein the second optical transmission facility is designed to emit at least one second optical localization signal in the surrounding area of the imaging modality,
at least one optical receiving element, which can be arranged on the portable component, wherein the at least one optical receiving element is designed to receive the emitted first and second optical localization signal, and
an electronic evaluation unit, which can be arranged outside an examination room in which the imaging modality can be arranged.

The electronic evaluation unit may be connected to the at least one optical receiving element by means of an optical transmission path, so that the received first and second optical localization signal can be transmitted to the electronic evaluation unit. The electronic evaluation unit may be configured to localize the portable component on the basis of the first and second optical localization signal.

Specifically, the explanations for the method in accordance with the fourth aspect apply likewise (analogously) for the localization system in accordance with the fifth aspect.

In one form of embodiment of the further aspect (fifth aspect) it is provided that the first optical transmission facility is connected to the electronic evaluation unit by means of a first optical transmission path and the second optical transmission facility is connected to the electronic evaluation unit by means of a second optical transmission path, in particular the at least one optical transmission path, the first optical transmission path and the second optical transmission path being designed as optical waveguides.

In particular, the at least one optical transmission path and the further optical transmission path can be designed as optical waveguides. Specifically, these can be fiber optic lines or fiber optic connections. Thus the corresponding optical signals can here for example be transmitted from the transmitting and receiving unit to the evaluation unit via optical fibers. Thanks to this optical signal transmission, no substantially negative interference can be made or occur to the imaging procedure within the examination room. Furthermore, the influence of the strong magnetic fields or electromagnetic fields in the examination room on the signal processing can be minimized, since for example the optical fibers are here less influenced by the imaging system and the corresponding evaluation is performed outside the examination room and outside the interfering fields.

A further aspect (sixth aspect) of the disclosure relates to an imaging system having an imaging modality, at least one portable component and an electronic localization system in accordance with the previous aspect (fifth aspect) or an advantageous development thereof. The system may configured such that:
the first optical transmission facility is arranged spaced apart from the imaging modality,
the second optical transmission facility is arranged spaced apart from the first optical transmission facility and from the imaging modality,
the at least one optical receiving element is arranged on the portable component, and
the electronic evaluation unit is arranged outside an examination room, wherein the imaging modality is arranged in the examination room.

Advantageous embodiments of one aspect of the disclosure can be regarded as advantageous embodiments of one of the other aspects. In particular, advantageous forms of embodiment of one aspect can be regarded as advantageous forms of embodiment of all other aspects. This also applies vice versa.

The embodiments of the imaging system can advantageously be used in accordance with the third aspect. In particular, the electronic localization system in accordance with the second aspect can also be used in respect of the embodiments of the electronic localization system of the fifth aspect. This also applies vice versa.

For example, the method in accordance with the first aspect can also advantageously be used to perform the method in accordance with the fourth aspect. This also applies vice versa.

In particular, the electronic localization systems and/or the imaging systems can have (technical) means in order to execute or perform at least one of the methods of the aspects of the disclosure.

The disclosure also includes developments of the inventive electronic localization systems and of the inventive imaging systems which have features as already described in connection with the developments of the inventive methods. For this reason, the corresponding developments of the inventive electronic localization systems and of the inventive imaging systems are not described again here.

Embodiments of one aspect are to be regarded as advantageous embodiments of the other aspect and vice versa. The disclosure also includes the combinations of the features of the forms of embodiment described.

In the exemplary embodiments, the components described each represent individual features of the disclosure, to be considered independently of one another, which each also develop the disclosure independently of one another and thus are also to be regarded as part of the disclosure individually or in a combination other than the one shown. Furthermore, the exemplary embodiments described can also be supplemented by further of the features of the disclosure already described.

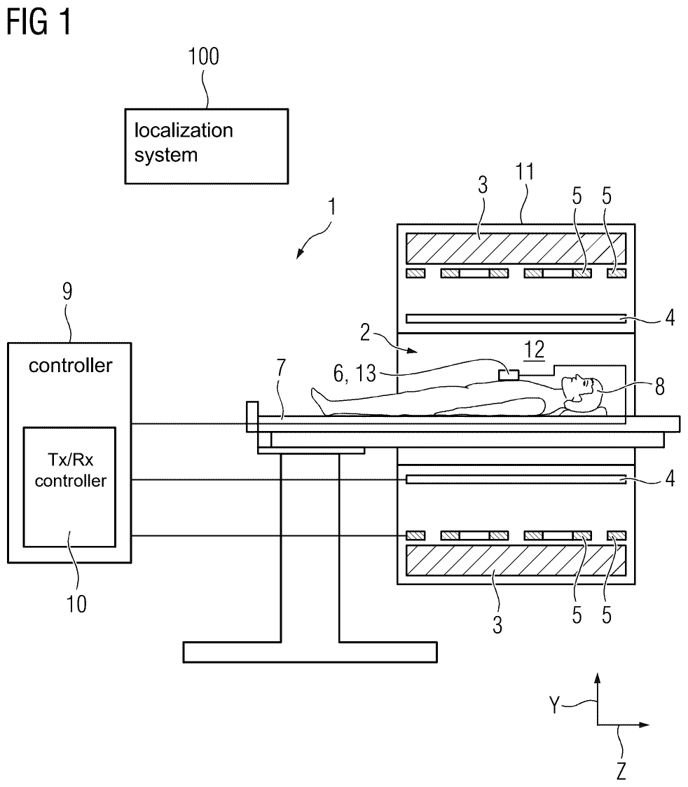

FIG. 1 shows a schematic representation of an exemplary form of embodiment of an imaging system 1. The imaging system 1 can optionally be an MRT system (also referred to as a magnetic resonance system).

The imaging system 1 may comprise a magnet unit with a field magnet 3, which generates a static magnetic field for the orientation of nuclear spins of an object, for example a patient 8, in an imaging area 12. The imaging area 12 is characterized by an extremely homogeneous static magnetic field, wherein the homogeneity relates in particular to the magnetic field strength or the amplitude thereof. The imaging area 12 is situated in a patient tunnel 2, which extends through the magnet unit in a longitudinal direction Z. The field magnet 3 can for example be a superconducting magnet, which can generate magnetic fields with a magnetic flux density of up to 3 T or more. However, for lower field strengths use can also be made of permanent magnets or electromagnets with normally conducting coils. A patient table or examination table 7 can be movable inside the patient tunnel 2.

The magnet unit may further comprise at least one gradient coil 5. It is likewise conceivable for the gradient coil 5 to consist of an array of multiple sub-gradient coils. The gradient coil 5 is used to overlay the static magnetic field with gradient fields, i.e. location-dependent magnetic fields, in the three spatial directions for the spatial differentiation of the scanned image areas in the imaging area. The gradient coil 5 can for example be designed as a coil consisting of normally conducting wires, which for example can generate fields or field gradients orthogonal to one another in the imaging area.

The magnet unit may comprise a transmitting coil array, which for example can comprise a body coil 4 (also referred to as a whole-body coil) as a transmitting antenna, which is designed to radiate a radio-frequency signal or excitation signal into the imaging area. The body coil 4 can hence be understood as an RF transmitting coil array of the imaging system 1 or as part of the RF transmitting coil array. In one or more embodiment, the body coil 4 can also be used to receive resonant MR signals that are emitted by the object. In this case the body coil 4 can also be considered as part of a signal capture apparatus of the imaging system 1. The signal capture apparatus optionally may comprise a local coil 6, which can be arranged in the immediate vicinity of the object, for example on the object or in the patient table 7. The local coil 6 can alternatively or additionally to the body coil 4 serve as a receiving coil or receiving antenna.

The imaging system 1 also may comprise a control and computing system (controller) 9. The control and computing system 9 can comprise a transmit/receive controller 10, which is connected to the body coil 4, the gradient coil 5 and/or the local coil 6. As a function of the captured MR signals the transmit/receive controller 10, which can comprise an analog-to-digital converter (ADC), can generate corresponding MR data, in particular in k-space. The transmit/receive controller 10 is where appropriate also connected to the body coil 4 and controls it for the generation of RF pulses, such as excitation pulses and/or refocusing pulses. The transmit/receive controller 10 of the control and computing system (controller, system controller) 9 can furthermore also be connected to the gradient coil 5 and controls it, in order to switch slice selection gradients, gradients for the frequency encoding and/or phase encoding and/or readout gradients. The control and computing system (controller) 9 may include processing circuitry that is configured to perform one or more functions/operations of the controller 9. Additionally, or alternatively, one or more components (e.g. Tx/Rx controller 10) of the controller 9 may include processing circuitry that is configured to perform one or more respective functions/operations of the component(s).

For example, the MRT system 1 has an imaging modality 11. The imaging modality 11 can include at least the magnet unit, the patient table 7 and the patient tunnel 2.

To be able to increase the safety of the patient 8 during the examination procedure by means of the imaging system 1 and to increase the image quality and/or image reconstruction as regards the images acquired of the patient 8 using the imaging modality 11, it is important for the respective current position and/or localization of the patient 8 to be known. The position and/or movement of the local coil 6 is especially important here. This local coil 6 is arranged directly on the patient 8, in particular is fastened to the patient 8, in order to be able to perform corresponding image acquisitions or scans. By tracking the local coil 6, it would be possible to work with coils which move during the measurement or between the measurements, for example if the patient 8 breathes, or is repositioned for a different measurement. In the second case, it could possibly be necessary to resort to fewer adjustment sequence measurements, which could speed up the workflow.

Since the local coil 6 is thus a portable component on the patient 8, it is also possible, by localizing this local coil 6 as a portable component 13, to correspondingly localize the patient 8. Besides the local coil 6 as a portable component 13, it would likewise be applicable for special clothing, objects or other apparatuses to be included here, which can be supported by the patient 8 at least in part.

To remedy this, the present disclosure can be used to perform an improved, more efficient and/or safe localization of the portable component 13 and thus of the patient 8. For this purpose, an electronic localization system 100 is inventively provided. This electronic localization system 100 can consist of multiple individual components which can be integrated into the imaging system 1. The electronic localization system 100 is designed to determine the localization of the portable component 13 and thus of the patient 8 on the basis of optical signals, for example on the basis of light beams. This has the advantage in particular that it can be integrated into the imaging system 1 simply and with little effort. A further advantage is that this optical evaluation for the localization exerts little influence on the actual measurements as regards the imaging system 1. This also applies vice versa.

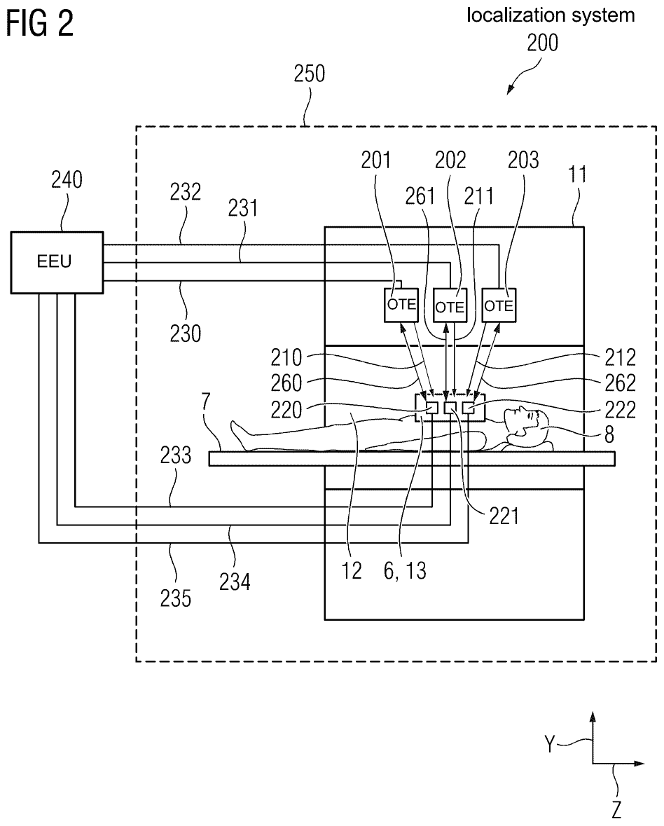

The subsequent FIG. 2 shows a schematic representation of an exemplary form of embodiment of the electronic localization system 100. In this case a possible configuration with an exemplary electronic localization system 200 is represented here. The configurations as regards the localization system 200 represented here can likewise apply to the localization system 100.

The localization system 200 has at least one optical transmission element 201. It is likewise conceivable for the localization system 200 to have further optical transmission elements 202, 203. The optical transmission elements 201-203 can be arranged on the imaging modality 11. In this case the optical transmission elements 201-203 are especially arranged so that they can emit optical signals inside the patient tunnel 2 and thus inside the imaging area 12. As shown by way of example in FIG. 2, the optical transmission elements 201-203 viewed in the y-direction can be arranged above the patient 8 in the area of the imaging modality 11, so that the optical transmission elements 201-203 viewed from above can carry out or perform optical signals in the direction of the patient table 7. An optical localization signal 210 can especially be emitted with the at least one transmission element 201. Accordingly, the optical transmission elements 202 and 203 can in turn be used to emit optical localization signals 211 and 213. In this case a light beam, a laser beam or another optical signal can for example be emitted with the optical localization signal 210.

In order to be able to receive the at least one emitted optical localization signal 2, the localization system 200 can have at least one optical receiving element 220. Likewise, further such receiving elements 221 and 222 can in turn be provided. As already mentioned in the introduction, a localization of the portable component 13 is to be performed. Accordingly, the receiving elements 220-222 can be designed so that they can be arranged in and/or fastened to the portable component 13, in this case the local coil 6.

As shown by way of example in FIG. 2, the patient 8 can lie on the patient table 7 and support, or have, the portable component 13, here the local coil 6. In this case the receiving elements 220-222 can in turn be arranged on the portable component so that they can be directed toward the transmission elements 201 - 203. Thus the emitted optical localization signals 210-212 can be received by the receiving elements 220 - 222.

The transmission elements 201-203, and the receiving elements 220-222, can each be connected or coupled to an electronic evaluation unit (processor, controller) 240 of the localization system 200 via an optical transmission path 230-235. These optical transmission paths 230-235 may be optical waveguides, such as optical fiber cables. Thus, the signal transmission can take place optically via a respective optical fiber. This has the advantage that such optical fibers do not interfere with the operation of the imaging system 1 due to electromagnetic fields or radiation. Since the evaluation is in turn sensitive, the electronic evaluation unit 240 is designed so that it can be arranged outside an examination room 250 of the imaging system 1. The electronic evaluation unit 240 may include processing circuitry that is configured to perform one or more functions/operations of the electronic evaluation unit 240. Additionally, or alternatively, one or more components of the electronic evaluation unit 240 may include processing circuitry that is configured to perform one or more respective functions/operations of the component(s).

Situated in this examination room 250 is the imaging modality 11, so that in this examination room 250, there are strong magnetic fields as regards the imaging and strong radio-frequency signals can for example occur inside the examination room 250. These could impair, such as distort, the processing. Hence the optical signals are conducted from the examination room 250 into the evaluation unit 240 arranged outside the examination room 250 via optical fibers. On the basis of the transmitted information regarding the emission of the optical localization signals 201-203 and in turn the receipt of these optical localization signals 201-203, the localization of the portable component 13 can be performed.

With the help of the localization system 200 it is possible to ensure that the image quality is improved as regards the imaging system 1, since with the help of the localization system 200 it is possible to perform continuous position tracking of the portable component 13 and thus of the patient 8 during imaging. By continuously measuring the position of the portable component 13 and thus of the patient 8 it is possible to use flexible coils, such as the local coil 6, which can be supported closer to the body of the patient 8. The scan workflow can thereby be accelerated, since no adjustment sequence measurements need be performed. For example, the transmission elements 201-203 can be arranged on a torus in respect of the imaging modality 11, as shown schematically in FIG. 2. The transmission elements 201-203 can, when viewed from the inside, i.e. visible inside the patient tunnel 2, be designed to be able to perform a maximally efficient emission of the optical localization signals 210-212. These optical localization signals 210-212 can for example be referred to as “time-of-flight signals”. Thanks to a plurality of light receiving apparatuses, such as the receiving elements 220-222, these emitted signals can be received.

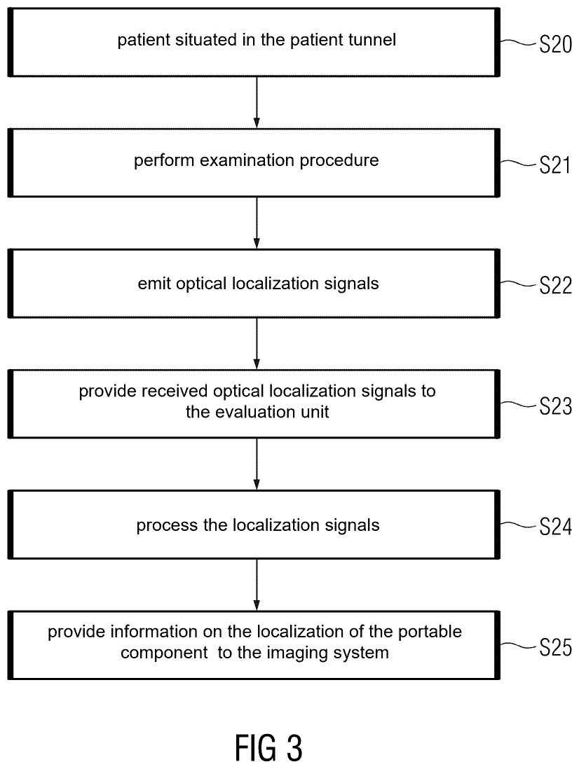

In the subsequent FIG. 3 an exemplary operational sequence for the localization of the portable component 13 with the help of the localization system 100, in particular here with the localization system 200, is explained.

In an optional step S20 the patient 8 can be situated in the patient tunnel 2 and can have at least the portable component 13. It is likewise conceivable for the patient 8 to have multiple such portable components, such as multiple local coils. This depends on the measurement procedure or examination procedure.

In a subsequent step S21 the examination procedure, i.e. the scan procedure, on the patient 8 now takes place. To continuously perform localization, optical localization signals 210-212 may be emitted in step S22. Optical localization signals can especially be emitted continuously during the examination procedure at regular intervals, such as permanently.

For example, the transmission elements 201-203 can be configured, or controlled, so that the optical localization signals 210-212 are configured differently from each other. What is common here is that the optical localization signals 210-212 each have different wavelengths from one another. Here, a differently configured light beam or light can be emitted. In other words, the optical localization signals 210-212 can be emitted as red light, green light or blue light, or another light color or color. This in turn has the advantage that a precise assignment and thus selection or selecting of the received signals can be performed when receiving. Thus it is possible to assign the transmission element 201-203 from which the respectively received optical localization signal 210-212 was emitted.

In a subsequent optional step S23 the received optical localization signals 210-212 can be transmitted to the evaluation unit 240. In addition, corresponding information about the transmission procedures of the transmission elements 201 - 203 can likewise be transmitted to the evaluation unit 240 via the optical fibers.

In an optional subsequent step S24 the evaluation unit 240 can process the localization signals 210-212. In this case a signal propagation time, i.e. a propagation time, can initially be determined or calculated based on a propagation time procedure as regards a respective emitted received localization signal 210-212. Using the calculated respective signal propagation time a respective spacing 260, 261 and 262 can in turn be ascertained. The spacing 260 can for example be between the transmission element 201 and the receiving element 220, the spacing 261 between the transmission element 211 and 221, and the spacing 262 between the transmission element 230 and 222. In other words, a distance or range between the respective transmitter and receiver can also be ascertained based on the signal propagation time. Information about the position of the receiving element 220-222 can then in turn be determined. For this purpose, account can furthermore be taken of which respective length the optical transmission paths 230-295 have. Thus, this can in turn be performed when determining the signal propagation time and in particular the spacing outside the examination room 250. In other words, the “time-of-flight measurements” can be performed by conducting the optical signals via the optical fibers, which have a known length, outside the examination room 250 and calculating them there accordingly. In other words, the emitted light can be checked to see how long the light from a respective transmission element 201-203 to a respective receiving element 220-222 needed in order to cover this respective distance.

Trilateration can in turn be used to ascertain the position of the respective receiving elements 220-222 and thus the position of the portable component 13.

In an optional subsequent step S25 information on this localization of the portable component 13 can correspondingly be made available to the imaging system 1, meaning that parameters relating to imaging can be influenced or adjusted during imaging or parameters of reconstruction after imaging.

In other words, with the help of the localization system 200 it is possible to track the coil positions of the imaging system 1 with the help of “time-of-flight signals”, which are transmitted via optical fibers. This means interference by the strong magnetic field, the gradients or RF signals can be prevented.

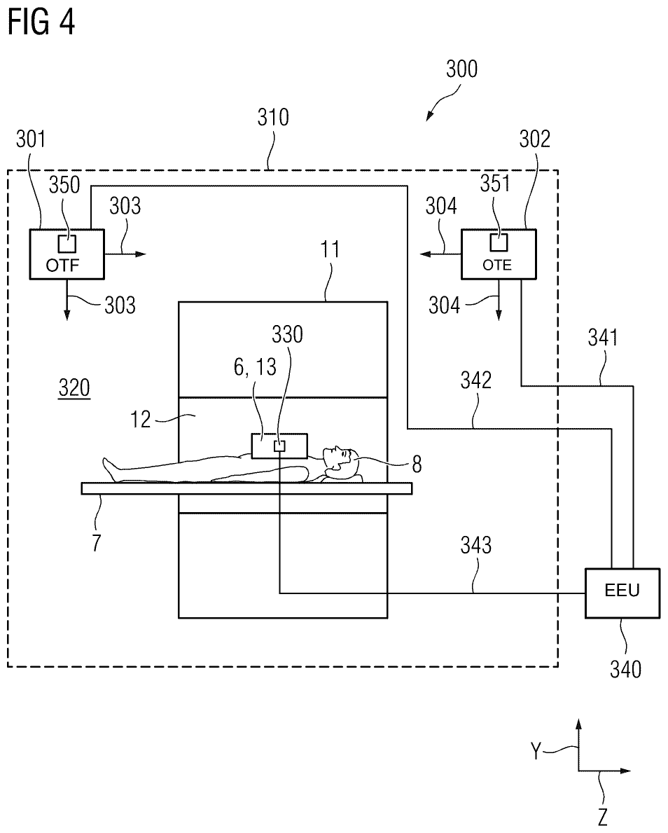

FIG. 4 shows a further configuration as regards the localization system 100. In this context, a localization system 300 is now explained in greater detail below. This is a further possible configuration for the localization of the portable components 6, 13. Explanations as regards the localization system 200 can likewise be applied for the localization system 300 explained here. This can also apply vice versa.

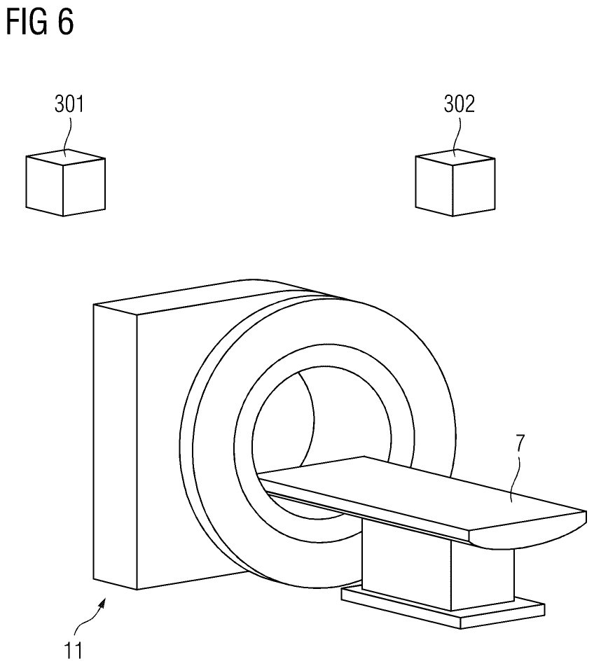

In this case the localization system 300 can now have at least two transmission facilities 301, 302. These optical transmission facilities 301, 302 can be arranged spaced apart from one another and in each case spaced apart from the imaging modality 11 inside an examination room 310. Situated inside the examination room 310 are thus the imaging modality 11 and the transmission facilities 301, 302. These transmission facilities 301, 302 can be laser units. These can be configured as laser towers, which can for example be arranged in the area of a wall or ceiling of the examination room 310. FIG. 6 further shows how the transmission facilities 301, 302 can be arranged in respect of the image modality 11. With the help of the transmission facilities 301, 302 at least one optical localization signal 303, 304 can be emitted in each case. These optical localization signals, i.e. emission signals, 303, 304, are optionally emitted into a surrounding area 320 of the imaging modality 11 and thus of the imaging system 1.

For example, the transmission facilities 301, 302 can be configured so that they can be emitted between localization signals 303, 304 as laser lines. The optical localization signal 303 can be referred to as the first localization signal and the localization signal 304 as the second localization signal.

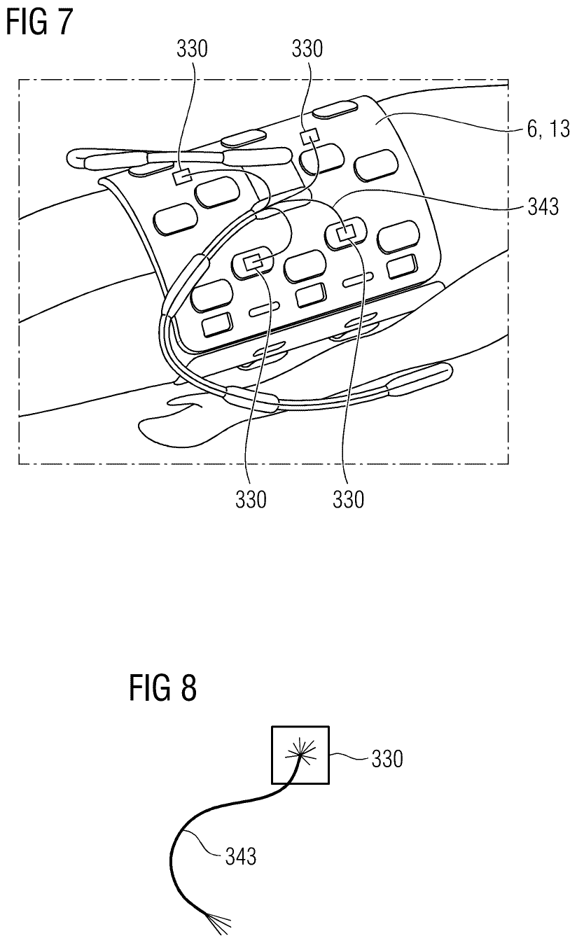

The emission of the localization signals 303, 304 can take place such that laser lines cross or pass through the room, i.e. the surrounding area 320, in two orientations. This means that first for example the optical localization signal 303 is emitted as a laser line horizontally, i.e. directed downward, i.e. in the negative y-direction. Then in turn the localization signal 303 or a similar signal in this respect can be emitted sideways by means of a vertical laser light, for example in the positive or negative z-direction. In other words, similarly to a grid, laser light or light beams can be emitted within the surrounding area 320, which means the largest possible area can be covered from a sensory point of view. This can be performed correspondingly by the respective transmission facility 301, 302. To receive the emitted optical localization signals 303, 304 the localization system 300 has at least one optical receiving element 330. The optical receiving element 330 can be configured similarly to the receiving elements 201 to 203 explained for the localization signal system 200. However, for better receipt or capture of the emitted optical signals the receiving element 330 can be configured as a receiving photodiode. The receiving element 330 can in turn be arranged on the surface of the portable component 13. In this case multiple such receiving elements 330 can especially in turn be correspondingly arranged. The one exemplary representation of multiple such receiving elements 330 on the component 13 is for example shown by way of example in FIG. 7.

As already explained for the configuration of the localization system 200, the localization system 300 likewise has a corresponding electronic evaluation unit (processor, controller) 340. This evaluation unit 340 can be configured similarly to the evaluation unit 240 and is likewise in turn situated outside the examination room 310. The transmission facilities 301, 302 can be connected to the evaluation unit via optical transmission paths 341, 342. These can in turn be similar configurations to the transmission paths 230 to 235. With the help of the receiving element 330 the emitted optical signals can thus be received and transmitted to the evaluation unit 340 via an optical transmission path 343. The optical transmission paths 341 to 343 can in turn be optical fiber lines, i.e. not waveguides. For this purpose, it is for example shown by way of example in FIG. 8 how the optical transmission path 343, i.e. an optical fiber, can be optically coupled to the receiving element 330. The electronic evaluation unit 340 may include processing circuitry that is configured to perform one or more functions/operations of the electronic evaluation unit 340. Additionally, or alternatively, one or more components of the electronic evaluation unit 340 may include processing circuitry that is configured to perform one or more respective functions/operations of the component(s).

Based on the emitted and received localization signals 303, 304 a position determination of the receiving element 330 and thus of the component 13 can be performed by means of the evaluation unit 340.

With the help of the localization system 300 a camera-free localization method for coils, such as the local coil 6, and in particular portable components 13 using a combination of laser and optical fibers can be enabled. This can likewise be implemented with the localization system 100 and 200. The localization system 100/200 may include processing circuitry that is configured to perform one or more functions/operations of the localization system.

As already mentioned, the receiving element 330 can be designed as an optical fiber. In this case this optical fiber can have an entry aperture or an aperture in order especially to be able to receive the light, or a laser beam as an optical localization signal. In this case, the fibers can advantageously be bundled with the cabling of the coil 6, i.e. the component 13, and connected to the receiving unit via a connector (identical to the one used for the receipt of the RF signal) of the coil 6, without interference of the RF signal.

So that the laser signal, i.e. an optical localization signal, can be coupled into the optical fiber, the “total internal reflection” (TIR) should be considered here. In this case the laser light should enter the fiber within the critical angle for TIR. Because of this, when using the optical fiber as a receiving element 330, a bundle of optical fibers can be used, which use the entry point for example at the flex-coil as a component 3. Thus a larger angular range as regards the capture can be covered. The bundle of optical fibers can correspondingly be fixed to the component 13. For example, such a bundle or fiber bundle can be fastened with a transparent adhesive to a surface of the component 13. In this way the laser light, i.e. the optical signal, can be coupled into at least one fiber, regardless of the orientation of the entry point of the laser to the fiber bundle.

For example, the optical signal can be emitted such that for example it is emitted with a laser in the range of 60 Hertz. This enables a tracking frequency for the coil order and patient tracking including the detection of breathing by the patient, so that especially a sequence as regards the evaluation can be triggered.

For example, the coil 6 can be a flexible coil, so that here multiple fiber bundles can be attached at a wide variety of points on this coil.

As regards patient tracking it is conceivable for the component 13 to be an item similar to a piece of clothing, which can be placed on the patient 8, in order to localize or monitor said patient 8 as regards movement and position.

With the help of the localization system 300 a high level of position accuracy can especially be performed compared to known possibilities. Thus cameras can be dispensed with here, which is advantageous as regards perception and confidentiality as regards the patient 8.

The transmission facilities 301, 302 can be designed outside the imaging modality 11. These can for example be arranged in front of and behind the tube. A laser signal visible to the human eye can for example be detected over more than ten meters. Likewise, there is the possibility as regards a compromise between the type of laser scan, which defines the tracking rate, and the exposure degradation time at the sensor, as well as the aperture size and optical fiber. With a higher tracking rate, fewer signals enter the fiber with the same laser power. The lasers would have to be visible to the eye, which limits their performance somewhat. A fast-changing laser can be stronger compared to a stationary laser and nevertheless be safe for the eye. Thus if a laser that is safe for the eye per se cannot be employed, a stronger laser which vibrates faster could be used.

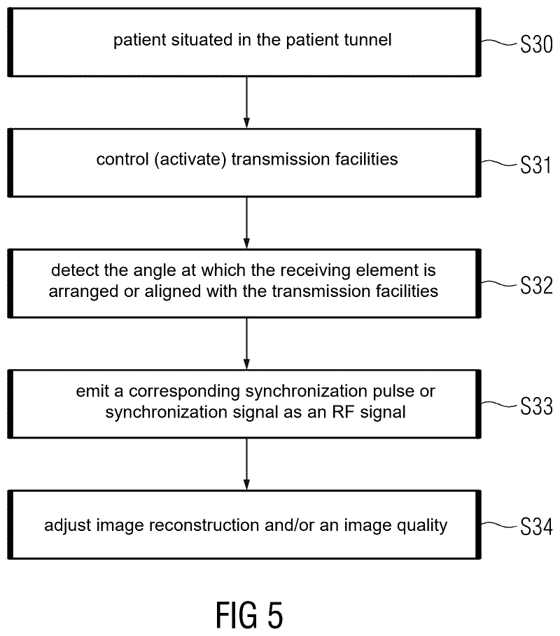

In the subsequent FIG. 5 an exemplary operational sequence is explained, for how the localization of the component 13 and thus of the patient 8 can be performed specifically with the localization system 300.

In an optional step S30 the patient 8 can be situated in the patient tunnel 2 and can have at least the portable component 13. It is likewise conceivable for the patient 8 to have multiple such portable components, such as multiple local coils. This depends on the measurement procedure or examination procedure.

In a subsequent optional step S31 the transmission facilities 301, 302 can be correspondingly controlled and in particular activated. This takes place in particular immediately prior to an examination procedure or scan procedure on the patient 8. In particular, the transmission facilities 301, 302 can continuously emit corresponding optical signals, such as laser beams. In order especially to be able to prepare the receiving elements accordingly for a receipt, use of made of synchronization signals, in particular at least one synchronization signal. This ensures that the system is correspondingly synchronized for the evaluation and in particular for the localization. Two types can be used for this. In one embodiment, the two transmission facilities 301, 302 can emit a synchronization pulse, which can be diffuse, in the infrared range. This can capture the entire range as regards the imaging modality 11.

The at least one receiving element 330 or multiple such receiving elements can detect the synchronization pulse and then count the time until the moving laser beams are detected. Thus a signal propagation time can be ascertained here on the basis of the synchronization signal and the emitted and received localization signals 303, 304. In this case a first signal propagation time can be ascertained as regards the first localization signal 303 and a second signal propagation time as regards a second localization signal 304.

This information can in turn be used to detect the angle at which the receiving element 330 is arranged or aligned with the transmission facilities 303, 302 in each case. This can take place in an optional step S32. In order to obtain sufficient information about the position and orientation of the component 13, it is particularly advantageous if multiple receiving elements are used. Mathematical calculations, for example triangulation, can be used to perform a localization of the component 13 on the basis of the multiple angle measurements.

A further possibility as regards synchronization is to emit a corresponding synchronization pulse or synchronization signal as an RF (radio frequency) signal. This can take place in an optional step S33. This can be emitted for example by means of coils of the imaging system 1 and received by transmitting units 350, 351 of the transmission facilities 301, 302. Thus the transmission facilities 301, 302 here can synchronize themselves on the basis of this synchronization signal. Especially in this case, the laser lines which are emitted through the examination room 250 can be correspondingly synchronized.

In an optional step S34, an image reconstruction and/or an image quality can be adjusted as regards imaging on the basis of the localization performed.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,”or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

1. A method for localizing a portable component of an imaging system during an examination procedure on a patient using an imaging modality of the imaging system, the portable component being arranged on the patient for the examination procedure, the method comprising:
emitting, by at least one optical transmission element, at least one optical localization signal in an imaging area of the imaging modality, within which the patient is located during the examination procedure, by at least one optical transmission element;
receiving the at least one emitted optical localization signal by at least one optical receiving element arranged on the portable component;
transmitting, by an optical transmission path and to an electronic evaluation unit, the at least one received optical localization signal, by an optical transmission path to an electronic evaluation unit, wherein the electronic evaluation unit is situated outside an examination room in which the imaging modality is arranged; and
localizing the portable component by the electronic evaluation unit based on the at least one received optical localization signal.

2. The method as claimed in claim 1, wherein a signal propagation time of the emitted and received at least one optical localization signal is determined by the electronic evaluation unit based on the at least one received optical localization signal, wherein transmission information about the emission of the at least one optical localization signal is provided to the electronic evaluation unit and the signal propagation time is determined based on the transmission information.

3. The method as claimed in claim 2, wherein:
a spacing between the at least one optical transmission element and the at least one optical receiving element is determined by the electronic evaluation unit based on the signal propagation time, a position of the at least one optical receiving element being determined based on the determined spacing; and
the portable component is localized based on the position of the at least one optical receiving element.

4. The method as claimed claim 1, further comprising:
emitting, with at least one further optical transmission element and in addition to the at least one optical localization signal, which has a first wavelength, at least one further optical localization signal, which has a second wavelength different from the first wavelength; and
receiving the at least one further optical localization signal by the at least one optical receiving element or at least one further optical receiving element, which is arranged on the portable component,
wherein the localizing the portable component is further based on the at least one received further optical localization signal.

5. An electronic localization system for localizing a portable component of an imaging system during an examination procedure on a patient using an imaging modality of the imaging system, the portable component being arranged on the patient for the examination procedure, the electronic localization system comprising:
at least one optical transmitter configured to be arranged on the imaging modality and emit at least one optical localization signal in an imaging area of the imaging modality, within which the patient is situated during the examination procedure;
at least one optical receiver configured to be arranged on the portable component and receive the at least one emitted optical localization signal; and
an electronic evaluation unit configured to:
be arranged outside an examination room in which the imaging modality is arranged, wherein the electronic evaluation unit is connected to the at least one optical receiver by an optical transmission path to transmit the at least one received optical localization signal to the electronic evaluation unit, and
localize the portable component based on the at least one received optical localization signal.

6. The electronic localization system as claimed in claim 5, wherein the at least one optical transmitter is connected to the electronic evaluation unit by a further optical transmission path.

7. The electronic localization system as claimed in claim 6, wherein the at least one optical transmission path and the further optical transmission path are optical waveguides.

8. An imaging system comprising:
an imaging modality;
at least one portable component; and
an electronic localization system according to claim 5, wherein:
the at least one optical transmitter is arranged on the imaging modality,
the at least one optical receiver is arranged on the portable component, and
the electronic evaluation unit is arranged outside an examination room, the imaging modality being arranged in the examination room.

9. A method for localizing a portable component of an imaging system during an examination procedure on a patient using an imaging modality of the imaging system, the portable component being arranged on the patient for the examination procedure, the method comprising:
emitting at least one first optical localization signal in a surrounding area of the imaging modality by a first optical transmission facility, which is arranged spaced apart from the imaging modality in the surrounding area;
emitting at least one second optical localization signal in the surrounding area of the imaging modality by a second optical transmission facility, which is arranged spaced apart from the first optical transmission facility and which is arranged spaced apart from the imaging modality in the surrounding area;
receive the emitted first and second optical localization signal by at least one optical receiving element, which is arranged on the portable component;
transmitting the received first and second optical localization signal by an optical transmission path to an electronic evaluation unit situated outside an examination room in which the imaging modality is arranged; and
localizing the portable component by the electronic evaluation unit based on the first and second optical localization signal.

10. The method as claimed in claim 9, further comprising:
determining a first angle between the first optical transmission facility and the at least one optical receiving element based on the received first optical localization signal; and
determining a second angle between the second optical transmission facility and the at least one optical receiving element based on the received second optical localization signal,
wherein transmission information about the emission of the first and second optical localization signal is provided to the electronic evaluation unit and the first and second angle determinations being based on the transmission information.

11. The method as claimed in claim 10, wherein a position of the at least one optical receiving element is determined on the basis of the angle determinations, and the portable component is localized on the basis of the position of the at least one optical receiving element.

12. The method as claimed in claim 9, wherein at least one synchronization signal is sent to the at least one receiving element with the first and/or second optical transmission facility, wherein the receipt of the first and second optical localization signal is performed based on the synchronization signal received by the at least one receiving element.

13. The method as claimed in claim 10, wherein:
the first and second optical localization signals each sweep the surrounding area in a defined rhythm as a laser line in an alternately different orientation, and
from a point in time of the receipt of the at least one synchronization signal, a period of time is determined based on when at least one of the emitted laser lines is received by the receiver, the first and second angles being determined based on the determined period of time.

14. An electronic localization system for localizing a portable component of an imaging system during an examination procedure on a patient using an imaging modality of the imaging system, the portable component being arranged on the patient for the examination procedure, the electronic localization system comprising:
a first optical transmitter configured to be spaced apart from the imaging modality and emit at least one first optical localization signal in a surrounding area of the imaging modality;
a second optical transmitter arranged spaced apart from the first optical transmitter and configured to be arranged spaced apart from the imaging modality and emit at least one second optical localization signal in the surrounding area of the imaging modality;
at least one optical receiver configured to be arranged on the portable component and configured to receive the emitted first optical localization signal and the emitted second optical localization signal; and
an electronic evaluation unit configured to:
be arranged outside an examination room in which the imaging modality is arrangeable, wherein the electronic evaluation unit is connected to the at least one optical receiver by an optical transmission path to transmit the received first and second optical localization signals to the electronic evaluation unit, and
localize the portable component based on the received first and second optical localization signals.

15. The electronic localization system as claimed in claim 14, wherein the first optical transmitter is connected to the electronic evaluation unit by a first optical transmission path and the second optical transmitter is connected to the electronic evaluation unit by a second optical transmission path.

16. The electronic localization system as claimed in claim 15, wherein the first optical transmission path and the second optical transmission path are optical waveguides.

17. An imaging system comprising:
an imaging modality;
at least one portable component; and
an electronic localization system according to claim 14, wherein:
the first optical transmitter is arranged spaced apart from the imaging modality,
the second optical transmitter is arranged spaced apart from the first optical transmitter and from the imaging modality,
the at least one optical receiver is arranged on the portable component, and
the electronic evaluation unit is arranged outside the examination room, the imaging modality being arranged in the examination room.

18. One or more non-transitory media storing instructions that, when executed by one or more processors, cause the one or more processors to perform the method claim 1.

19. One or more non-transitory media storing instructions that, when executed by one or more processors, cause the one or more processors to perform the method claim 9.
